(19) United States
(12) Patent Application Publication
(10) Pub. No.: US 2025/0161803 A1
(43) Pub. Date: May 22, 2025

(54) GAMEPAD FOR HEAD-MOUNTED DEVICE, AND HEAD-MOUNTED DEVICE

(71) Applicant: Beijing Zitiao Network Technology Co., Ltd., Beijing (CN)

(72) Inventors: Xuebing DENG, Beijing (CN); Xiaowei MA, Beijing (CN); Xuebin GAO, Beijing (CN); Zhaomeng LIU, Beijing (CN)

(21) Appl. No.: 18/839,650

(22) PCT Filed: Mar. 15, 2023
(86) PCT No.: PCT/CN2023/081584

§ 371 Date: Aug. 19, 2024

(30) Foreign Application Priority Data
Mar. 24, 2022 (CN) 202210302826.8
Mar. 24, 2022 (CN) 202210303366.0

(51) Int. Cl. A63F 13/285; A63F 13/211; A63F 13/235; A63F 13/24; A63F 13/327; G01R 33/07

(52) U.S. Cl. CPC A63F 13/285; A63F 13/211; A63F 13/235; A63F 13/24; A63F 13/327; G01R 33/072

(57) ABSTRACT

A gamepad (100) for a head-mounted device, and a head-mounted device are provided. The gamepad (100) includes: a housing (10); a processor (11), wherein the processor (11) is arranged inside the housing (10), and the processor (11) is in signal transmission with a host of the head-mounted device; a driving apparatus (20), wherein the driving apparatus (20) is arranged inside the housing (10), and the driving apparatus (20) is electrically connected to the processor (11) to receive an instruction signal transmitted by the processor (11); and a vibration apparatus (30), wherein the vibration apparatus (30) is arranged inside the housing (10); the vibration apparatus (30) has various different vibration frequencies; and the driving apparatus (20) is connected to the vibration apparatus (30) to control, according to the received instruction signal, the vibration apparatus (30) to vibrate at the corresponding vibration frequencies.

### CROSS-REFERENCE TO RELATED APPLICATION(S)

This application is proposed and claims priority to Chinese Patent Application No. 202210302826.8 filed on Mar. 24, 2022 and Chinese Patent Application No. 202210303366.0 filed on Mar. 24, 2022, which are incorporated by reference in their entireties.

### FIELD

The present application relates to the technical field of gamepads, and in particular, to a gamepad for a head-mounted device, and a head-mounted device with the gamepad for a head-mounted device.

### BACKGROUND

In the related technology, a head-mounted device (such as a pair of virtual reality (VR) glasses) and a gamepad work together. With the development of the VR industry, consumers have an increasing requirement for gaming experiences. The existing gamepad is internally provided with a vibration apparatus. The vibration apparatus can only generate simple vibrations based on a turn on/off command. The vibration apparatus cannot adjust a vibration frequency as a game scene changes. As a result, the gamepad has a poor use experience, affecting the gaming experience of a user.

### SUMMARY

The present application aims to at least solve one of the technical problems in the existing technology. To this end, the present application provides a gamepad for a head-mounted device. The gamepad for the head-mounted device can adjust a vibration frequency of a vibration apparatus as a game scene changes, thereby enhancing the use experience of the gamepad and enhancing the gaming experience of a user.

The present application further provides a head-mounted device.

According to the gamepad for the head-mounted device of the present application, the gamepad includes: a housing; a processor, wherein the processor is arranged inside the housing, and the processor is in signal transmission with a host of the head-mounted device; a driving apparatus, wherein the driving apparatus is arranged inside the housing, and the driving apparatus is electrically connected to the processor to receive an instruction signal transmitted by the processor; and a vibration apparatus, wherein the vibration apparatus is arranged inside the housing; the vibration apparatus has various different vibration frequencies; and the driving apparatus is connected to the vibration apparatus to control, according to the received instruction signal, the vibration apparatus to vibrate at the corresponding vibration frequencies.

According to the gamepad for the head-mounted device of the present application, by the cooperation of the processor, the driving apparatus, and the vibration apparatus, a vibration frequency of the vibration apparatus can be adjusted as a game scene changes, so that a user can obtain game scene information. During a game, the user can take control of the game scene in time and can quickly and accurately make a judgment and responses, thereby enhancing the use experience of the gamepad and enhancing the gaming experience of the user.

The additional aspects and advantages of the present application will be partially provided in the following descriptions, some of which will become apparent from the following descriptions, or learned through the practice of the present application.

### BRIEF DESCRIPTION OF THE DRAWINGS

FIG. 1 is a schematic diagram of a gamepad according to an embodiment of the present application;

FIG. 2 is a sectional view of a gamepad according to an embodiment of the present application;

FIG. 3 is a working principle diagram of a processor, a driving apparatus, and a vibration apparatus according to an embodiment of the present application;

FIG. 4 is a working principle diagram of a processor, a driving apparatus, a force feedback assembly, and an angle sensor according to an embodiment of the present application;

FIG. 5 is a schematic diagram of assembling of a button, a motor, and a push rod assembly according to an embodiment of the present application;

FIG. 6 is a schematic diagram of an internal structure of a gamepad according to an embodiment of the present application;

FIG. 7 is a working principle diagram of a processor, a driving apparatus, a force feedback assembly, and a Hall sensor according to an embodiment of the present application;

FIG. 8 is a working principle block diagram of a gamepad according to an embodiment of the present application;

FIG. 9 is a schematic diagram of a left gamepad according to an embodiment of the present application; and

FIG. 10 is a schematic diagram of a right gamepad according to an embodiment of the present application.

### DETAILED DESCRIPTION OF EMBODIMENTS

The embodiments of the present application are described in detail below, and examples of the embodiments are shown in accompanying drawings, where the same or similar elements or the elements having same or similar functions are denoted by the same or similar reference numerals throughout the description. The embodiments described below with reference to the accompanying drawings are exemplary and used only for explaining the present application, and should not be construed as a limitation on the present application.

In the descriptions of the present application, it should be understood that orientations or positional relationships indicated by “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “anticlockwise”, “axial”, “radial”, “circumferential” and the like are orientations or positional relationships as shown in the drawings, and are only for the purpose of facilitating and simplifying the descriptions of the present application instead of indicating or implying that devices or elements indicated must have particular orientations, and be constructed and operated in the particular orientations, so that these terms are not construed as limiting the present application. In addition, features defined as “first” and “second” explicitly or implicitly include one or more of the features. In the descriptions of the present application, “a plurality” means two or more, unless otherwise specified.

In the description of the present application, it should be noted that unless otherwise specified and limited, the terms “mount”, “connect”, and “connection” should be broadly understood. For example, it can be a fixed connection, detachable connection, integrated connection, mechanical connection, electrical connection, direct connection, indirect connection via an intermediate element, or internal communication between two elements. A person of ordinary skill in the art can understand the specific meanings of the above terms in the present application according to specific situations.

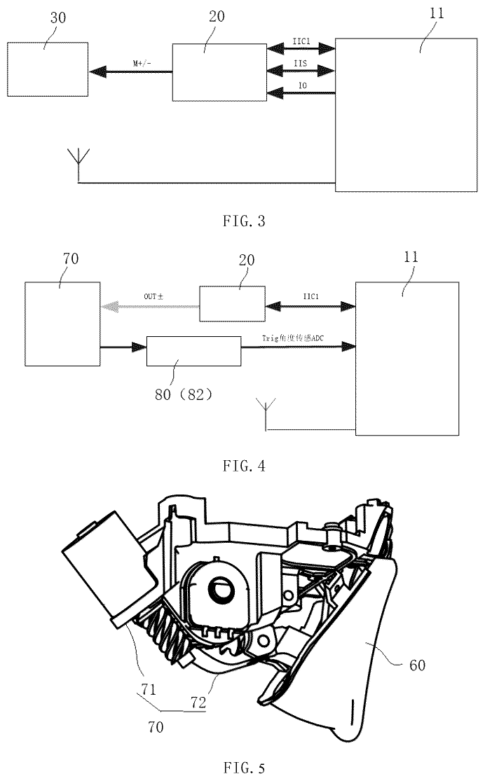

A gamepad 100 for a head-mounted device according to an embodiment of the present application will be described below with reference to FIG. 1 to FIG. 10. The head-mounted device may be a pair of VR glasses. The head-mounted device is worn on the head of a user. The head-mounted device includes a host.

As shown in FIG. 1 to FIG. 3, the gamepad 100 according to an embodiment of the present application includes: a housing 10, a processor 11, a driving apparatus 20, and a vibration apparatus 30. The processor 11 is arranged inside the housing 10 and the processor 11 is in signal transmission with the host of the head-mounted device. The driving apparatus 20 is arranged inside the housing 10. The driving apparatus 20 is electrically connected to the processor 11. The driving apparatus 20 can receive an instruction signal transmitted by the processor 11. The driving apparatus 20 may be a driver chip with an Internet Information Services (IIS) audio input interface. The vibration apparatus 30 is arranged inside the housing 10. The vibration apparatus 30 may be a motor. The motor is a wideband linear motor with a wide frequency response range. The vibration apparatus 30 has various different vibration frequencies. The driving apparatus 20 is connected to the vibration apparatus 30. The driving apparatus 20 may control, according to the received instruction signal, the vibration apparatus 30 to vibrate at the corresponding vibration frequencies.

One instruction signal may correspond to one game scene. The host generates different instruction signals according to different game scenes. When a user is playing a game, the gamepad 100 is connected to the head-mounted device to perform signal connection between the processor 11 and the host. When there is a vibration scene in the game, the host generates an instruction signal that is in line with a vibration frequency of the vibration apparatus 30 in the current game scene. Then, the host transmits the generated instruction signal to the processor 11, and the processor 11 transmits the instruction signal to the driving apparatus 20. The driving apparatus 20 controls, according to the received instruction signal, the vibration apparatus 30 to vibrate at the corresponding vibration frequency. Moreover, in different game scenes, the vibration frequency of the vibration apparatus 30 varies, so that a user has different feelings when holding the gamepad 100. Different hand feelings can be simulated. For example, a smaller vibration frequency of the vibration apparatus 30 indicates a less vibration sensation of the gamepad 100, and a larger vibration frequency of the vibration apparatus 30 indicates a greater vibration sensation of the gamepad 100. It can also be understood that a smaller vibration frequency of the vibration apparatus 30 indicates higher stickiness of gamepad 100, and a larger vibration frequency of the vibration apparatus 30 indicates lower stickiness of the gamepad 100. Therefore, by the cooperation of the processor 11, the driving apparatus 20, and the vibration apparatus 30, an effect of adjusting the vibration frequency of the vibration apparatus 30 as the game scene changes can be achieved. A user can obtain game scene information when holding the gamepad 100. During a game, the user can take control of the game scene in time and can quickly and accurately make a judgment and responses, thereby enhancing the use experience of the gamepad 100 and enhancing the gaming experience of the user.

Therefore, by the cooperation of the processor 11, the driving apparatus 20, and the vibration apparatus 30, the vibration frequency of the vibration apparatus 30 can be adjusted as the game scene changes, so that a user can obtain game scene information. During a game, the user can take control of the game scene in time and can quickly and accurately make a judgment and responses, thereby enhancing the use experience of the gamepad 100 and enhancing the gaming experience of the user.

In some embodiments of the present application, as shown in FIG. 1, the gamepad 100 may further include a hanging ring 90. The hanging ring 90 is mounted on the housing 10. When a user holds the gamepad 100, the hanging ring 90 is hung on the wrist of the user to prevent the gamepad 100 from falling off from the hand of the user.

In some embodiments of the present application, the instruction signal may be configured as an audio signal, and the driving apparatus 20 controls, according to different received audio signals, the vibration apparatus 30 to vibrate. One audio signal may correspond to one game scene. When there is a vibration scene in a game, the host may extract a sound effect track content in the game scene for algorithm optimization to generate an audio file that is in line with a vibration frequency of the vibration apparatus 30 in the current game scene. Then, the host may wirelessly transmit the generated audio file to the processor 11. The processor 11 may transmit the audio file to the driving apparatus 20 through an IIS audio signal. The driving apparatus 20 may then control, according to the received audio signal, the vibration apparatus 30 to vibrate at the corresponding vibration frequency. This setting can achieve an effect of controlling the vibration frequency of the vibration apparatus 30 according to a sound effect in the game scene. It can better adjust the vibration frequency of the vibration apparatus 30 as the game scene changes. During a game, a user can take control of the game scene more timely and can more quickly and accurately make a judgment and responses, thereby further enhancing the use experience of the gamepad 100 and further enhancing the gaming experience of the user.

In some embodiments of the present application, the processor 11 may be provided with a wireless transmission module, and the wireless transmission module wirelessly is in signal transmission with the host. Further, the wireless transmission module may be Bluetooth and/or WiFi, and processor 11 may transmit a signal to the host through Bluetooth and/or WiFi. However, the present application is not limited to this. Or, the processor 11 may transmit a signal to the host through another wireless transmission mode that play the same role as Bluetooth and/or WiFi. This setting can prevent the processor 11 from being connected to the host through a wiring harness, which can prevent the wiring harness from pulling the gamepad 100 and the head-mounted device, thereby avoiding a limitation on the movement of the gamepad 100, further enhancing the use experience of the gamepad 100, and enhancing user satisfaction.

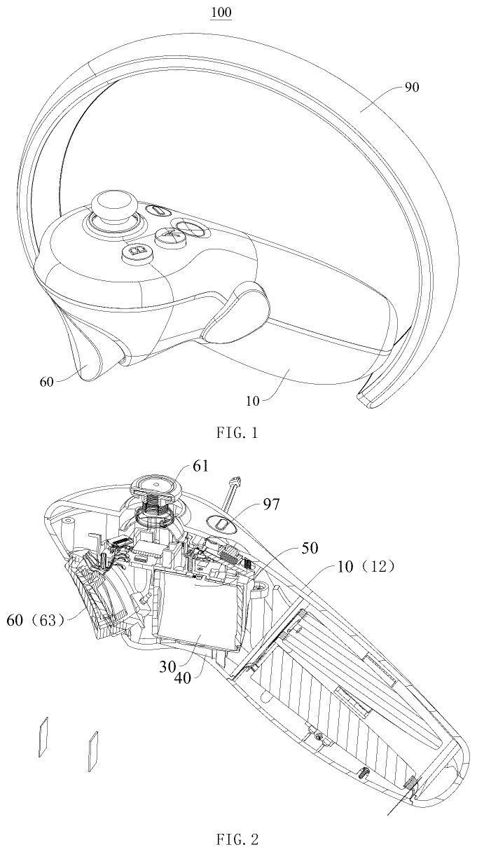

In some embodiments of the present application, as shown in FIG. 2, a buffer piece 40 is arranged between the vibration apparatus 30 and an inner circumferential wall of the housing 10. The buffer piece 40 is sandwiched between the vibration apparatus 30 and the inner circumferential wall of the housing 10, and the buffer piece 40 has a buffering effect. When the vibration apparatus 30 vibrates, the buffer piece 40 can buffer the vibration of the vibration apparatus 30 to make the vibration of the gamepad 100 more gentle, thereby improving the sensation of a user holding the gamepad 100.

Further, the buffer piece 40 may be configured as foam which has a good buffering effect. This setting can ensure the buffering effect of the buffer piece 40 to make the vibration of the gamepad 100 more gentle, thereby further improving the sensation of a user holding the gamepad 100. Furthermore, the foam is cheap, so that the manufacturing cost of the gamepad 100 can be reduced.

In some embodiments of the present application, as shown in FIG. 2, the gamepad 100 further includes a mounting bracket 50. The mounting bracket 50 is arranged inside the housing 10. The mounting bracket 50 is sleeved on the vibration apparatus 30. Further, as shown in FIG. 2, the mounting bracket 50 defines a mounting space with an opened lower end. The vibration apparatus 30 is arranged inside the mounting bracket 50 through the opened end of the mounting space, and the buffer piece 40 is arranged between a lower surface of the vibration apparatus 30 and the inner circumferential wall of the housing 10. The mounting bracket 50 is fixed to an inner wall of the housing 10 to locate the vibration apparatus 30 in the housing 10. The mounting bracket 50 may be mounted at the housing 10 through a bolt or a screw. This setting can securely mount the mounting bracket 50 in the housing 10, so that the vibration apparatus 30 can be reliably located in the housing 10. In addition, it is convenient to mount and remove the mounting bracket 50 and to replace and repair the vibration apparatus 30. However, the present application is not limited to this. The mounting bracket 50 may alternatively be clamped onto the housing 10.

In some embodiments of the present application, the gamepad 100 is further provided with a button 60; the button 60 is electrically connected to the processor 11; and when the button 60 is triggered, the processor 11 receives a signal and transmits the signal to the host. The button 60 has a control function, such as a confirm control function, a shooting control function, a return control function, and the like. When the button 60 is pressed, the button 60 may transmit a function signal corresponding to the button 60 to the processor 11, and the processor 11 may transmit the function signal corresponding to the button 60 to the host. After receiving the function signal corresponding to the button 60, the host may control the head-mounted device to perform a corresponding operation.

In some embodiments of the present application, as shown in FIG. 4 to FIG. 7, the gamepad 100 may further include: a force feedback assembly 70 and a detector 80 configured to detect a position of the button 60. The detector 80 is electrically connected to the processor 11. When a user presses the button 60, the detector 80 may detect the position of the button 60 relative to the housing 10 in real time. After the detector 80 detects the position of the button 60 relative to the housing 10, the detector 80 transmits detection information to the processor 11, and the processor 11 determines the position of the button 60 according to the received detection information. The force feedback assembly 70 is electrically connected to the processor 11. The force feedback assembly 70 is fitted with the button 60 to apply a feedback force to the button 60. The force feedback assembly 70 controls a magnitude and direction of the feedback force according to the signal transmitted by the processor 11. It should be noted that one game scene may correspond to the magnitude and direction of one feedback force, and the button 60 plays a very important role in a game experience link. An existing button can only provide a pressure sensation to a finger of a user when pressed, and the button 60 cannot push the finger.

In the present application, when there is a scene where force feedback needs to be performed on the button 60 in a game, the host determines a force feedback mode according to a need, such as, determining the magnitude and direction of the feedback force. The host then optimizes the feedback force into a control signal through an algorithm. The host transmits the control signal to the processor 11 in a wireless manner. After receiving the control signal, the processor 11 transmits the control signal to the driving apparatus 20, and the driving apparatus 20 drives force feedback assembly 70 to operate, so that the force feedback assembly 70 applies the feedback force to the button 60. The button 60 can push the fingers, so that when the fingers are pushed, an effect of adjusting the magnitude and direction of the feedback force applied by the force feedback assembly 70 to the button 60 as the game scene changes. A user can feel a change in force feedback, namely, a change in the tactile sensation. During the operation performed on the gamepad 100, the user may experience many rich tactile sensations, thereby enhancing the use experience of the gamepad 100 and further enhancing the gaming experience of the user.

Specifically, when a user presses the button 60, and there is a scene where force feedback needs to be performed on the button 60 in a game, the driving apparatus 20 drives the force feedback assembly 70 to work, so that the force feedback assembly 70 applies a feedback force to the button 60. In the process of pressing the button 60, the user has a tactile sensation when sensing the feedback force, so that a good use experience is achieved. A magnitude and direction of the feedback force are controlled through the force feedback assembly 70, so that the feedback force sensed by the user changes, namely, the tactile sensation changes. In the game scene, a multi-scene tactile sensation can be provided for the user. For example, in a game scene of a hitting force, after the existing button 60 is pressed, a hitting function in the game scene is triggered. This button 60 cannot provide a feedback of an exact hitting force of 6 N or 8 N. In the present application, the force feedback assembly 70 controls the magnitude and direction of the feedback force. Under different hitting forces, the button 60 can obtain different feedback forces. Further, if the hitting force is 6 N, the button 60 obtains a feedback force of 2 N. If the hitting force is 8 N, the button 60 obtains a feedback force of 3 N. In this case, during the operation performed on the gamepad 100 by a user, the rich tactile experience can be added, and the gaming experience is enhanced.

In some embodiments of the present application, as shown in FIG. 4 to FIG. 6, the force feedback assembly 70 includes: a motor 71 and a push rod assembly 72. The push rod assembly 72 is fitted with the button 60 and the motor 71 respectively. The push rod assembly 72 converts rotation of motor 71 into movement to apply the feedback force to the button 60. The push rod assembly 72 may be connected between the button 60 and an output shaft of the motor 71. When the motor 71 works, the output shaft of the motor 71 rotates, and the push rod assembly 72 converts the rotation of the output shaft into movement. When the push rod assembly 72 moves towards or away from the button 60, the push rod assembly 72 can apply the feedback force to the button 60, so that a user can feel the feedback force, thereby adding the rich tactile experience. Specifically, when the output shaft of the motor 71 rotates in one of a clockwise direction and a counterclockwise direction, the push rod assembly 72 converts the rotation of the output shaft into movement. The push rod assembly 72 moves towards the button 60. The push rod assembly 72 may apply a feedback force of a thrust to the button 60. When the output shaft of the motor 71 rotates in the other one of the clockwise direction and the counterclockwise direction, the push rod assembly 72 converts the rotation of the output shaft into movement. The push rod assembly 72 carrying the button 60 moves away from the button 60, and the push rod assembly 72 may apply a feedback force of a pulling force to the button 60.

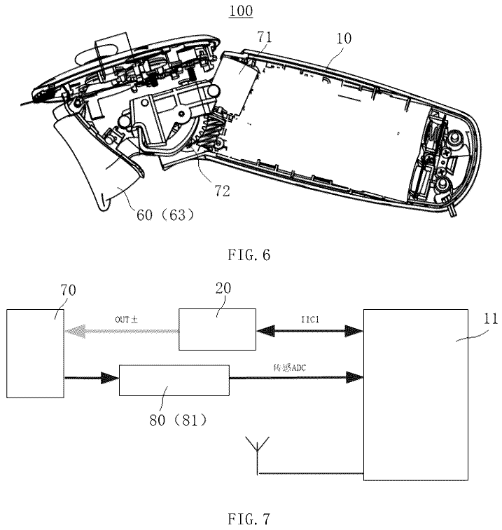

In some embodiments of the present application, as shown in FIG. 5 and FIG. 6, the button 60 is configured as a rotatably arranged trigger. The trigger may be mounted at the housing 10 through a pivot shaft. The trigger may rotate around the pivot shaft, and the detector 80 is configured as an angle sensor 82. In a game scene of a hitting force, a user presses the trigger to rotate to trigger a hitting function in the game scene. The force feedback assembly 70 controls a magnitude and direction of the feedback force. Under different hitting forces, the button 60 can obtain different feedback forces. Moreover, the angle sensor 82 detects a rotation angle of the trigger relative to the housing 10 in real time. The detector 80 transmits detection information to the processor 11, and the processor 11 determines the position of the button 60 according to the received detection information.

In some embodiments of the present application, the force feedback assembly 70 includes: an energized coil and a magnetic member. The energized coil is arranged inside the housing 10; the energized coil is electrically connected to the processor 11; the processor 11 controls a magnitude and direction of current of the energized coil. The magnetic member is arranged at the button 60. Further, the magnetic member is mounted on the button 60. The magnetic member may be arranged between the energized coil and the button 60. The direction and magnitude of the current of the energized coil are changed through the processor 11, so that a direction and intensity of a magnetic field generated by the energized coil are changed, thereby changing a direction and magnitude a force on the magnetic member. When a user presses the button 60, the button 60 drives the magnetic member to move in a direction close to the energized coil. The processor 11 controls the energized coil to generate current in a first direction, and the processor 11 controls the energized coil to generate a magnetic field. The magnetic field generated by the energized coil and a magnetic field generated by the magnetic member repel each other. When the magnetic member is subjected to a repulsive force, the repulsive force is fed back to the button 60. In the process of pressing the button 60, the user receives a force feedback generated by the repulsive force and then has a tactile sensation, so that the gamepad 100 has a good use experience. In addition, the processor 11 controls the energized coil to generate current in a second direction. The second direction is opposite to the first direction. The processor 11 controls the energized coil to generate a magnetic field. The magnetic field generated by the energized coil and the magnetic field generated by the magnetic member attract each other. The magnetic member is subjected to an attractive force, and the attractive force is fed back to the button 60. In the process of pressing the button 60 by the user, the button 60 receives a force feedback generated by the attractive force, so that the gamepad 100 has a good use experience. The magnitude of the current of the energized coil changes, so that the intensity of the generated magnetic field changes, and the force feedback received by the user changes, namely, the tactile sensation changes.

Moreover, the magnetic member is mounted on the button 60, so that one of magnetic poles of the magnetic member faces the energized coil. There is a set distance between the magnetic member and the energized coil. The processor 11 controls the magnitude and direction of the current of the energized coil, thereby controlling the intensity of the magnetic field generated by the energized coil and then controlling the magnitude of the force on the magnetic member in the magnetic field. The force on the magnetic member in the magnetic field is fed back to the button 60 and then to the user, thereby enhancing the user experience. In a game scene, a multi-scene tactile sensation can be provided for a user. By changing the magnitude of the current of the electrified coil, different feedback sensations can be obtained in the process of pressing the button 60. Moreover, the feedback sensation may change in the process of pressing the button 60. For example, the feedback force increases or decreases.

For example, in a game scene with a hitting force, after the existing button 60 is pressed, a hitting function in the game scene is triggered. This button 60 cannot provide a feedback of an exact hitting force of 6 N or 8 N. In the present application, the processor 11 controls the magnitude and direction of the current of the energized coil. Under different hitting forces, the button 60 can obtain different feedback forces. Further, if the hitting force is 6 N, the button 60 obtains a feedback force of 2 N. If the hitting force is 8 N, the button 60 obtains a feedback force of 3 N. In this case, during the operation performed on the gamepad 100 by a user, the rich tactile experience can be added, and the gaming experience is enhanced.

Specifically, when a user presses the button 60, and there is a scene where force feedback needs to be performed on the button 60 in the game, the host determines a force feedback mode according to a need. The host then optimizes the data into a control signal. The host transmits the control signal to the processor 11. After receiving the control signal, the processor 11 transmits the control signal to the driving apparatus 20. The processor 11 controls the magnitude and direction of the current of the energized coil through the driving apparatus 20. The magnetic field generated by the energized coil and the magnetic field generated by the magnetic member repel each other. When the magnetic member is subjected to a repulsive force, the repulsive force is fed back to the button 60. In the process of pressing the button 60 by the user, a feedback force is applied to the user, and then the user has a tactile sensation, thereby achieving a good use experience.

Further, as shown in FIG. 7, the detector 80 may be configured as a Hall sensor 81. The Hall sensor 81 is fitted with the magnetic member to sense the position of the button 60. The Hall sensor 81 may detect a position of the magnetic member. After the Hall sensor 81 detects the position of the magnetic member, the Hall sensor 81 transmits position information of the magnetic member to the processor 11, and the processor 11 determines the position of the button 60 according to the received position information of the magnetic member.

As shown in FIG. 7 to FIG. 10, the gamepad 100 according to an embodiment of the present application includes: a housing 10, a sensor 66, a vibration apparatus 30, and a plurality of positioning light sources 64. The housing 10 is provided with a button 60. The housing 10 is internally provided with a processor 11 for transmitting a signal to the head-mounted device. The button 60 is electrically connected to the processor 11. When a user operates the button 60, the button 60 transmits a function signal corresponding to the button 60 to the processor 11, and the processor 11 transmits the received function signal corresponding to the button 60 to the head-mounted device. The head-mounted device controls a game scene in the head-mounted device according to the function signal corresponding to the button 60. For example, the button 60 may include a joystick 61 and a side button 62. The joystick 61 may be pulled in a plurality of directions. Preferably, the joystick 61 may be pulled in four directions. When a user pulls the joystick 61, the joystick 61 may transmit a switching function signal to the processor 11. The processor 11 transmits the received switching function signal to the head-mounted device. The head-mounted device controls the game scene in the head-mounted device to be switched according to the switching function signal. Moreover, the joystick 61 may be pressed down and clicked. When a user presses down and clicks the joystick 61, the joystick 61 may transmit a press-down and click function signal to the processor 11, and the processor 11 transmits the received press-down and click function signal to the head-mounted device. The head-mounted device controls the game scene in the head-mounted device to be switched. The side button 62 may control a grabbing operation. When a user presses the side button 62, the side button 62 may transmit a grabbing function signal to the processor 11. The processor 11 may transmit the received grabbing function signal to the head-mounted device. The head-mounted device controls, according to the grabbing function signal, the game scene in the head-mounted device to display a grabbing operation. This setting allows a user to control the game scene through the button 60 of the gamepad 100, and can enhance the gaming experience of the user.

Further, the plurality of positioning light sources 64 are arranged at the housing 10. The positioning light sources 64 may be configured as infrared lamps. The plurality of positioning light sources 64 are electrically connected to the processor 11, and the plurality of positioning light sources 64 are configured to be identified to determine a position of the gamepad 100. Further, the head-mounted device identifies positions of the plurality of positioning light sources 64 to determine the position of the gamepad 100. Specifically, after the plurality of positioning light sources 64 are turned on simultaneously, the processor 11 obtains a shape formed by light of the plurality of positioning light sources 64. The processor 11 transmits information of the shape formed by the light of the plurality of positioning light sources 64 to the head-mounted device. The head-mounted device determines a spatial position of gamepad 100 according to the information of the shape formed by the plurality of positioning light sources 64, and the head-mounted device may track and identify the position of the gamepad 100, so that the gamepad 100 has a high-precision positioning function. During a game, a user can move the gamepad 100 to change the positions of the plurality of positioning light sources 64, so as to point to content to be browsed in the game scene of the head-mounted device.

Further, the sensor 66 is arranged in housing 10. The sensor 66 is electrically connected to the processor 11, and the sensor 66 identifies a state and position of a finger of a user. When a user touches the sensor 66 with a finger, the sensor 66 may identify an action and position of the finger of the user. The sensor 66 may transmit information of the identified state (action) and position of the finger of the user to the processor 11. The processor 11 may transmit the information of the identified state and position of the finger of the user to the head-mounted device. The head-mounted device may identify the state and position of the finger of the user, thereby determining how many fingers the user uses to touch the sensor 66 and then identifying the state and position of the finger of the user during a game. It should be noted that when the sensor 66 is in no contact with a finger of the user, the sensor 66 may sense that a finger of the user approaches.

The vibration apparatus 30 is arranged inside the housing 10. The vibration apparatus 30 is electrically connected to the processor 11. The vibration apparatus 30 may be configured as a motor. The motor is a wideband linear motor with a wide frequency response range. The vibration apparatus 30 generates vibration according to a received signal. When there is a vibration scene in a game, the head-mounted device generates a vibration frequency signal that is in line with a vibration frequency of the vibration apparatus 30 in a current game scene. The head-mounted device then transmits the generated vibration frequency signal to the processor 11, and the processor 11 controls the vibration apparatus 30 to generate vibration, thereby enabling the gamepad 100 to have a vibration function.

Therefore, by cooperation of the sensor 66, the vibration apparatus 30, and the plurality of positioning light sources 64, the gamepad 100 can balance high-precision positioning, finger touch, and vibration functions, which can greatly enhance the gaming and scene experience, thereby enhancing the use experience of the gamepad 100 and enhancing the gaming experience of a user.

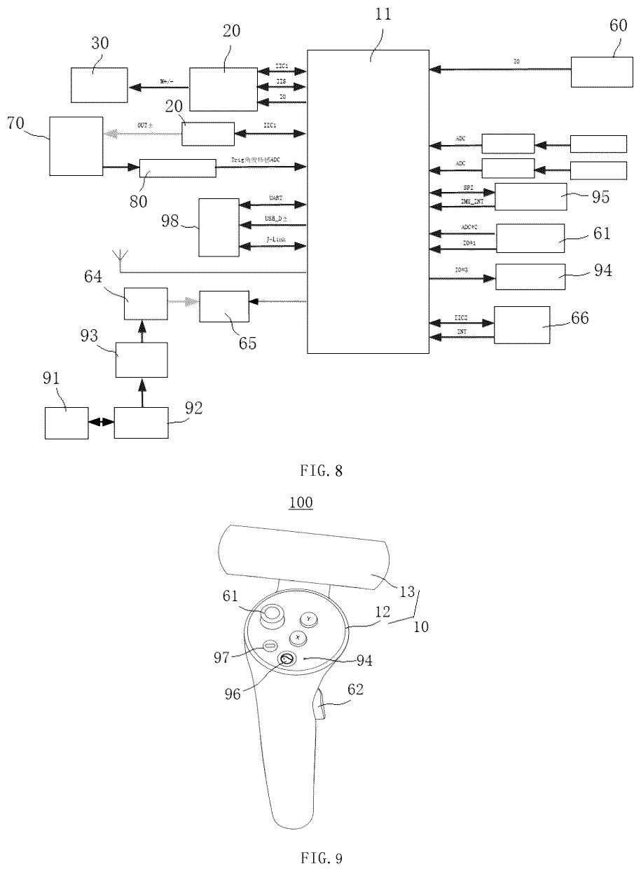

In some embodiments of the present application, as shown in FIG. 8, the vibration apparatus 30 has various vibration frequencies. The vibration frequencies of the vibration apparatus 30 may be adjusted. The gamepad 100 further includes a driving apparatus 20. The driving apparatus 20 is electrically connected to the vibration apparatus 30 and the processor 11, respectively. The driving apparatus 20 controls, according to an instruction signal transmitted by the processor 11, the vibration apparatus 30 to vibrate at the corresponding vibration frequencies. Further, the driving apparatus 20 is arranged inside the housing 10. The driving apparatus 20 can receive an instruction signal transmitted by the processor 11. The driving apparatus 20 may be a driver chip with an IIS audio input interface.

One instruction signal may correspond to one game scene. The head-mounted device generates different instruction signals according to different game scenes. When a user is playing a game, the gamepad 100 is connected to the head-mounted device to perform signal connection between the processor 11 and the head-mounted device. When there is a vibration scene in the game, the head-mounted device generates an instruction signal that is in line with a vibration frequency of the vibration apparatus 30 in the current game scene. Then, the head-mounted device transmits the generated instruction signal to the processor 11, and the processor 11 transmits the instruction signal to the driving apparatus 20. The driving apparatus 20 controls, according to the received instruction signal, the vibration apparatus 30 to vibrate at the corresponding vibration frequency. Moreover, in different game scenes, the vibration frequency of the vibration apparatus 30 varies, so that a user has different feelings when holding the gamepad 100. Different hand feelings can be simulated. For example, a smaller vibration frequency of the vibration apparatus 30 indicates a less vibration sensation of the gamepad 100, and a larger vibration frequency of the vibration apparatus 30 indicates a greater vibration sensation of the gamepad 100. It can also be understood that a smaller vibration frequency of the vibration apparatus 30 indicates higher stickiness of gamepad 100, and a larger vibration frequency of the vibration apparatus 30 indicates lower stickiness of the gamepad 100. Therefore, by the cooperation of the processor 11, the driving apparatus 20, and the vibration apparatus 30, an effect of adjusting the vibration frequency of the vibration apparatus 30 as the game scene changes can be achieved. A user can obtain game scene information when holding the gamepad 100. During a game, the user can take control of the game scene in time and can quickly and accurately make a judgment and responses, thereby enhancing the use experience of the gamepad 100 and enhancing the gaming experience of the user.

In some embodiments of the present application, the instruction signal may be configured as an audio signal, and the driving apparatus 20 controls, according to different received audio signals, the vibration apparatus 30 to vibrate. One audio signal may correspond to one game scene. When there is a vibration scene in a game, the head-mounted device may extract a sound effect track content in the game scene for algorithm optimization to generate an audio file that is in line with a vibration frequency of the vibration apparatus 30 in the current game scene. Then, the head-mounted device may wirelessly transmit the generated audio file to the processor 11. The processor 11 may transmit the audio file to the driving apparatus 20 through an IIS audio signal. The driving apparatus 20 may then control, according to the received audio signal, the vibration apparatus 30 to vibrate at the corresponding vibration frequency. This setting can achieve an effect of controlling the vibration frequency of the vibration apparatus 30 according to a sound effect in the game scene. It can better adjust the vibration frequency of the vibration apparatus 30 as the game scene changes. During a game, a user can take control of the game scene more timely and can more quickly and accurately make a judgment and responses, thereby further enhancing the use experience of the gamepad 100 and further enhancing the gaming experience of the user.

In some embodiments of the present application, the gamepad 100 may further include a hanging ring. The hanging ring is mounted on the housing 10. When a user holds the gamepad 100, the hanging ring is hung on the wrist of the user to prevent the gamepad 100 from falling off from the hand of the user.

In some embodiments of the present application, the processor 11 is provided with a wireless transmission module, and the gamepad 100 communicates with the head-mounted device through the wireless transmission module. Further, the wireless transmission module may be Bluetooth and/or WiFi, and processor 11 may transmit a signal to the head-mounted device through Bluetooth and/or WiFi. However, the present application is not limited to this. Or, the processor 11 may transmit a signal to the head-mounted device through another wireless transmission mode that play the same role as Bluetooth and/or WiFi. This setting can prevent the processor 11 from being connected to the head-mounted device through a wiring harness, which can prevent the wiring harness from pulling the gamepad 100 and the head-mounted device, thereby avoiding a limitation on the movement of the gamepad 100, further enhancing the use experience of the gamepad 100, and enhancing user satisfaction.

In some embodiments of the present application, the housing is provided with a plurality of buttons 60. At least one of the buttons 60 is provided with a force detector 80 and a force feedback assembly 70. For example: The plurality of buttons 60 include a trigger button 63. The trigger button 63 may achieve a confirm function and a shooting function. The detector 80 is configured to detect a position of the button 60. The detector 80 is electrically connected to the processor 11. When a user presses the button 60, the detector 80 may detect the position of the button 60 relative to the housing 10 in real time. After the detector 80 detects the position of the button 60 relative to the housing 10, the detector 80 transmits detection information to the processor 11, and the processor 11 determines the position of the button 60 according to the received detection information. The force feedback assembly 70 is electrically connected to the processor 11. The force feedback assembly 70 is fitted with the button 60 to apply a feedback force to the button 60. The force feedback assembly 70 controls a magnitude and direction of the feedback force according to the signal transmitted by the processor 11. It should be noted that one game scene may correspond to the magnitude and direction of one feedback force, and the button 60 plays a very important role in a game experience link. An existing button can only provide a pressure sensation to a finger of a user when pressed, and the button cannot push the finger.

In the present application, when there is a scene where force feedback needs to be performed on the button 60 in a game, the head-mounted device determines a force feedback mode according to a need, such as, determining the magnitude and direction of the feedback force. The head-mounted device then optimizes the feedback force into a control signal through an algorithm. The head-mounted device transmits the control signal to the processor 11 in a wireless manner. After receiving the control signal, the processor 11 transmits the control signal to the driving apparatus 20, and the driving apparatus 20 drives force feedback assembly 70 to work, so that the force feedback assembly 70 applies the feedback force to the button 60. The button 60 can push the fingers, so that when the fingers are pushed, an effect of adjusting the magnitude and direction of the feedback force applied by the force feedback assembly 70 to the button 60 as the game scene changes. A user can feel a change in force feedback, namely, a change in the tactile sensation. During the operation performed on the gamepad 100, the user may experience many rich tactile sensations, thereby enhancing the use experience of the gamepad 100 and further enhancing the gaming experience of the user.

Specifically, when a user presses the button 60, and there is a scene where force feedback needs to be performed on the button 60 in a game, the driving apparatus 20 drives the force feedback assembly 70 to work, so that the force feedback assembly 70 applies a feedback force to the button 60. In the process of pressing the button 60, the user has a tactile sensation when sensing the feedback force, so that a good use experience is achieved. A magnitude and direction of the feedback force are controlled through the force feedback assembly 70, so that the feedback force sensed by the user changes, namely, the tactile sensation changes. In the game scene, a multi-scene tactile sensation can be provided for the user. For example, in a game scene of a hitting force, after the existing button 60 is pressed, a hitting function in the game scene is triggered. This button 60 cannot provide a feedback of an exact hitting force of 6 N or 8 N. In the present application, the force feedback assembly 70 controls the magnitude and direction of the feedback force. Under different hitting forces, the button 60 can obtain different feedback forces. Further, if the hitting force is 6 N, the button 60 obtains a feedback force of 2 N. If the hitting force is 8 N, the button 60 obtains a feedback force of 3 N. In this case, during the operation performed on the gamepad 100 by a user, the rich tactile experience can be added, and the gaming experience is enhanced.

In some embodiments of the present application, as shown in FIG. 5 and FIG. 6, the force feedback assembly 70 includes: a motor 71 and a push rod assembly 72. The push rod assembly 72 is fitted with the button 60 and the motor 71 respectively. The push rod assembly 72 converts rotation of motor 71 into movement to apply the feedback force to the button 60. The push rod assembly 72 may be connected between the button 60 and an output shaft of the motor 71. When the motor 71 works, the output shaft of the motor 71 rotates, and the push rod assembly 72 converts the rotation of the output shaft into movement. When the push rod assembly 72 moves towards or away from the button 60, the push rod assembly 72 can apply the feedback force to the button 60, so that a user can feel the feedback force, thereby adding the rich tactile experience. Specifically, when the output shaft of the motor 71 rotates in one of a clockwise direction and a counterclockwise direction, the push rod assembly 72 converts the rotation of the output shaft into movement. The push rod assembly 72 moves towards the button 60. The push rod assembly 72 may apply a feedback force of a thrust to the button 60. When the output shaft of the motor 71 rotates in the other one of the clockwise direction and the counterclockwise direction, the push rod assembly 72 converts the rotation of the output shaft into movement. The push rod assembly 72 carrying the button 60 moves away from the button 60, and the push rod assembly 72 may apply a feedback force of a pulling force to the button 60.

In some embodiments of the present application, as shown in FIG. 4 to FIG. 6, the button 60 is configured as a rotatably arranged trigger button 63. The trigger button 63 may be mounted at the housing 10 through a pivot shaft. The trigger button 63 may rotate around the pivot shaft, and the detector 80 is configured as an angle sensor. In a game scene of a hitting force, a user presses the trigger button 63 to rotate to trigger a hitting function in the game scene. The force feedback assembly 70 controls a magnitude and direction of the feedback force. Under different hitting forces, the trigger button 63 can obtain different feedback forces. Moreover, the angle sensor detects a rotation angle of the trigger button 63 relative to the housing 10 in real time. The detector 80 transmits detection information to the processor 11, and the processor 11 determines the position of the trigger button 63 according to the received detection information.

In some embodiments of the present application, the force feedback assembly 70 includes: an energized coil and a magnetic member. The energized coil is arranged inside the housing 10; the energized coil is electrically connected to the processor 11; the processor 11 controls a magnitude and direction of current of the energized coil. The magnetic member is arranged at the button 60. Further, the magnetic member is mounted on the button 60. The magnetic member may be arranged between the energized coil and the button 60. The direction and magnitude of the current of the energized coil are changed through the processor 11, so that a direction and intensity of a magnetic field generated by the energized coil are changed, thereby changing a direction and magnitude a force on the magnetic member. When a user presses the button 60, the button 60 drives the magnetic member to move in a direction close to the energized coil. The processor 11 controls the energized coil to generate current in a first direction, and the processor 11 controls the energized coil to generate a magnetic field. The magnetic field generated by the energized coil and a magnetic field generated by the magnetic member repel each other. When the magnetic member is subjected to a repulsive force, the repulsive force is fed back to the button 60. In the process of pressing the button 60, the user receives a force feedback generated by the repulsive force and then has a tactile sensation, so that the gamepad 100 has a good use experience. In addition, the processor 11 controls the energized coil to generate current in a second direction. The second direction is opposite to the first direction. The processor 11 controls the energized coil to generate a magnetic field. The magnetic field generated by the energized coil and the magnetic field generated by the magnetic member attract each other. The magnetic member is subjected to an attractive force, and the attractive force is fed back to the button 60. In the process of pressing the button 60 by the user, the button 60 receives a force feedback generated by the attractive force, so that the gamepad 100 has a good use experience. The magnitude of the current of the energized coil changes, so that the intensity of the generated magnetic field changes, and the force feedback received by the user changes, namely, the tactile sensation changes.

Moreover, the magnetic member is mounted on the button 60, so that one of magnetic poles of the magnetic member faces the energized coil. There is a set distance between the magnetic member and the energized coil. The processor 11 controls the magnitude and direction of the current of the energized coil, thereby controlling the intensity of the magnetic field generated by the energized coil and then controlling the magnitude of the force on the magnetic member in the magnetic field. The force on the magnetic member in the magnetic field is fed back to the button 60 and then to the user, thereby enhancing the user experience. In a game scene, a multi-scene tactile sensation can be provided for a user. By changing the magnitude of the current of the electrified coil, different feedback sensations can be obtained in the process of pressing the button 60. Moreover, the feedback sensation may change in the process of pressing the button 60. For example, the feedback force increases or decreases.

For example, in a game scene with a hitting force, after the existing button 60 is pressed, a hitting function in the game scene is triggered. This button 60 cannot provide a feedback of an exact hitting force of 6 N or 8 N. In the present application, the processor 11 controls the magnitude and direction of the current of the energized coil. Under different hitting forces, the button 60 can obtain different feedback forces. Further, if the hitting force is 6 N, the button 60 obtains a feedback force of 2 N. If the hitting force is 8 N, the button 60 obtains a feedback force of 3 N. In this case, during the operation performed on the gamepad 100 by a user, the rich tactile experience can be added, and the gaming experience is enhanced.

Specifically, when a user presses the button 60, and there is a scene where force feedback needs to be performed on the button 60 in the game, the head-mounted device determines a force feedback mode according to a need. The host then optimizes the data into a control signal. The head-mounted device transmits the control signal to the processor 11. After receiving the control signal, the processor 11 transmits the control signal to the driving apparatus 20. The processor 11 controls the magnitude and direction of the current of the energized coil through the driving apparatus 20. The magnetic field generated by the energized coil and the magnetic field generated by the magnetic member repel each other. When the magnetic member is subjected to a repulsive force, the repulsive force is fed back to the button 60. In the process of pressing the button 60 by the user, a feedback force is applied to the user, and then the user has a tactile sensation, thereby achieving a good use experience.

Further, the detector 80 may be configured as a Hall sensor. The Hall sensor is fitted with the magnetic member to sense the position of the button 60. The Hall sensor may detect a position of the magnetic member. After the Hall sensor detects the position of the magnetic member, the Hall sensor transmits position information of the magnetic member to the processor 11, and the processor 11 determines the position of the button 60 according to the received position information of the magnetic member.

In some embodiments of the present application, as shown in FIG. 8, the gamepad 100 may further include an external port 98. The external port 98 is arranged at the housing 10. The external port 98 is suitable for being plugged to an external device to transmit a signal. The external port 98 is a communication and expansion interface. After the external port 98 is plugged to the external device, the function of the gamepad 100 can be expanded, and further the use experience of the gamepad 100 can be further enhanced.

In some embodiments of the present application, as shown in FIG. 8, the gamepad 100 may further include a power supply. The power supply may be a rechargeable battery 91. The rechargeable battery 91 is arranged inside the housing 10. The rechargeable battery 91 is electrically connected to the processor 11 to supply power to the gamepad 100. During working of the gamepad 100, the processor 11 may control the rechargeable battery 91 to supply power to parts that need power in the gamepad 100, thereby ensuring the normal work of the gamepad 100.

Further, as shown in FIG. 8, the gamepad 100 further includes a charging chip 92 and a power chip 93. The charging chip 92 is connected to both the rechargeable battery 91 and the power chip 93. The power chip 93 is further connected to the plurality of positioning light sources 64, thereby meeting a demand that the rechargeable battery 91 supplies power to the plurality of positioning light sources 64 to ensure the normal work of the plurality of positioning light sources 64.

Further, as shown in FIG. 8, a turn-on control chip 65 is connected between the processor 11 and the plurality of positioning light sources 64, and the turn-on control chip 65 is configured to control the plurality of positioning light sources 64 to be turned on.

Further, the gamepad 100 further includes a state indicator lamp 94. The state indicator lamp 94 is arranged at the housing 10. The state indicator lamp 94 may be configured as a three-color lamp. When the state indicator lamp 94 goes out, it indicates that the gamepad 100 has been connected to the head-mounted device or that the gamepad 100 has been turned off. When the state indicator lamp 94 flashes blue, it indicates that the gamepad 100 is being connected to the head-mounted device. When the state indicator lamp 94 is constantly on in blue, it indicates that the gamepad 100 is in a firmware upgrade mode. When the state indicator lamp 94 flashes alternately between red and blue slowly (0.5 seconds), it indicates that the gamepad 100 and the head-mounted device wait for pairing.

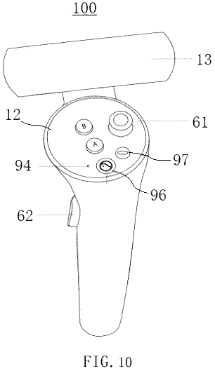

In some embodiments of the present application, as shown in FIG. 9 and FIG. 10, the housing 10 includes: a main body portion 12 and a ferrule 13. The button 60, the sensor 66, and the vibration apparatus 30 are respectively arranged at the main body portion 12, and the ferrule 13 is arranged at the main body portion 12. The ferrule 13 is formed into a hollow ring, and the plurality of positioning light sources 64 are arranged at the ferrule 13. Further, the plurality of positioning light sources 64 are arranged inside the ferrule 13. When a user moves the gamepad 100, the plurality of positioning light sources 64 may be driven to move together, making it convenient for the head-mounted device to track and identify the position of the gamepad 100. Moreover, the ferrule 13 may play a protection role for the plurality of positioning light sources 64, so as to avoid the plurality of positioning light sources 64 from being damaged by external objects, thereby prolonging the service lives of the plurality of positioning light sources 64. It should be noted that during the use of the gamepad 100, the plurality of positioning light sources 64 cannot be blocked.

In some embodiments of the present application, as shown in FIG. 8, the gamepad 100 may further include: an inertial measurement unit 95. The inertial measurement unit 95 is arranged inside the housing 10. The inertial measurement unit 95 is electrically connected to the processor 11. The inertial measurement unit 95 may measure a three-axis attitude angle (or an angular rate) and acceleration of the gamepad 100. The inertial measurement unit 95 transmits information of the three-axis attitude angle (or the angular rate) and acceleration of the gamepad 100 to the processor 11, and the processor 11 transmits the information of the three-axis attitude angle (or the angular rate) and acceleration of the gamepad 100 to the head-mounted device. The head-mounted device determines an attitude of the gamepad 100, namely, an action of the gamepad 100, according to the information of the three-axis attitude angle (or the angular rate) and acceleration of the gamepad 100.

In some embodiments of the present application, as shown in FIG. 9 and FIG. 10, the gamepad 100 includes a HOME button 96 and a return button 97. Both the HOME button 96 and the return button 97 may be connected to the processor 11. A short press is made on the HOME button 96 to power on the gamepad. A long press is made on the HOME button 96 for 6 seconds to power off the gamepad. A short press is made on the HOME button 96 to return to a main interface. The HOME button 96 is pressed for 1 second to correct a center of a screen. The return button 97 in a specific application program may be configured to achieve another function.

In some embodiments of the present application, as shown in FIG. 4, a buffer piece 40 is arranged between the vibration apparatus 30 and an inner circumferential wall of the housing 10. The buffer piece 40 is sandwiched between the vibration apparatus 30 and the inner circumferential wall of the housing 10, and the buffer piece 40 has a buffering effect. When the vibration apparatus 30 vibrates, the buffer piece 40 can buffer the vibration of the vibration apparatus 30 to make the vibration of the gamepad 100 more gentle, thereby improving the sensation of a user holding the gamepad 100.

Further, the buffer piece 40 may be configured as foam which has a good buffering effect. This setting can ensure the buffering effect of the buffer piece 40 to make the vibration of the gamepad 100 more gentle, thereby further improving the sensation of a user holding the gamepad 100. Furthermore, the foam is cheap, so that the manufacturing cost of the gamepad 100 can be reduced.

In some embodiments of the present application, as shown in FIG. 4, the gamepad 100 further includes a mounting bracket 50. The mounting bracket 50 is arranged inside the housing 10. The mounting bracket 50 sleeves the vibration apparatus 30. Further, as shown in FIG. 4, the mounting bracket 50 defines a mounting space with an opened lower end. The vibration apparatus 30 is arranged inside the mounting bracket 50 through the opened end of the mounting space, and the buffer piece 40 is arranged between a lower surface of the vibration apparatus 30 and the inner circumferential wall of the housing 10. The mounting bracket 50 is fixed to an inner wall of the housing 10 to locate the vibration apparatus 30 in the housing 10. The mounting bracket 50 may be mounted at the housing 10 through a bolt or a screw. This setting can securely mount the mounting bracket 50 in the housing 10, so that the vibration apparatus 30 can be reliably located in the housing 10. In addition, it is convenient to mount and remove the mounting bracket 50 and to replace and repair the vibration apparatus 30. However, the present application is not limited to this. The mounting bracket 50 may alternatively be clamped onto the housing 10.

A head-mounted device according to an embodiment of the present application includes: a host and a gamepad 100. The gamepad 100 is the gamepad 100 of the above embodiment. The processor 11 is in signal transmission with the host. The host generates different instruction signals according to different game scenes. When a user is playing a game, the gamepad 100 is connected to the head-mounted device to perform signal connection between the processor 11 and the host. When there is a vibration scene in the game, the host generates an instruction signal that is in line with a vibration frequency of the vibration apparatus 30 in the current game scene. Then, the host transmits the generated instruction signal to the processor 11, and the processor 11 transmits the instruction signal to the driving apparatus 20. The driving apparatus 20 controls, according to the received instruction signal, the vibration apparatus 30 to vibrate at the corresponding vibration frequency. Furthermore, in different game scenes, the vibration frequency of the vibration apparatus 30 varies, so that a user has different feelings when holding the gamepad 100. Different hand feelings can be simulated, so that an effect of adjusting the vibration frequency of the vibration apparatus 30 as the game scene changes can be achieved. A user can obtain game scene information when holding the gamepad 100. During a game, the user can take control of the game scene in time and can quickly and accurately make a judgment and responses, thereby enhancing the use experience of the head-mounted device and enhancing the gaming experience of the user. The gamepad 100 can balance high-precision positioning, finger touch, and vibration functions. By the cooperation between the gamepad 100 and the host, the gaming and scene experience can be greatly enhanced, thereby enhancing the use experience of the head-mounted device and enhancing the gaming experience of the user.

In the description of this specification, the description referring to the terms “one embodiment”, “some embodiments”, “exemplary embodiment” “an example”, “specific examples”, “some examples”, or the like means that specific features, structures, materials or characteristics described in connection with the embodiments or examples are included in at least one embodiment or example of the present application. In this specification, the schematic representations of the above terms are not necessarily intended to refer to the same embodiment or example. Furthermore, the specific features, structures, materials or characteristics described may be combined in any suitable manner in any one or more embodiments or examples.

Although the embodiments of the present application have been shown and described, it can be understood by those of ordinary skill in the art that various changes, modifications, substitutions, and variations can be made to these embodiments without departing from the principle and purpose of the present application. The scope of the present application is defined by the claims and their equivalents.

1. A gamepad for a head-mounted device, wherein the gamepad comprises:
a housing;
a processor arranged inside the housing and in signal transmission with a host of the head-mounted device;
a driving apparatus arranged inside the housing and electrically connected to the processor to receive an instruction signal transmitted by the processor; and
a vibration apparatus arranged inside the housing, the vibration apparatus having a plurality of different vibration frequencies, and the driving apparatus being connected to the vibration apparatus to control, according to the received instruction signal, the vibration apparatus to vibrate at the corresponding vibration frequencies.

2. The gamepad for the head-mounted device according to claim 1, wherein the instruction signal is an audio signal, and the driving apparatus controls, according to the received audio signal, the vibration apparatus to vibrate.

3. The gamepad for the head-mounted device according to claim 1, wherein the processor is provided with a wireless transmission module, and the wireless transmission module is in wireless signal transmission with the host.

4. The gamepad for the head-mounted device according to claim 1, wherein a buffer piece is arranged between the vibration apparatus and an inner circumferential wall of the housing.

5. The gamepad for the head-mounted device according to claim 1, wherein the gamepad further comprises a mounting bracket, the mounting bracket is sleeved on the vibration apparatus, and the mounting bracket is fixed to an inner wall of the housing to locate the vibration apparatus in the housing.

6. The gamepad for the head-mounted device according to claim 1, wherein the gamepad is further provided with a button, the button is electrically connected to the processor, and when the button is triggered, the processor receives a signal and is in signal transmission with the host.

7. The gamepad for the head-mounted device according to claim 6, further comprising:
a plurality of positioning light sources arranged at the housing, electrically connected to the processor and used for being identified to determine a position of the gamepad; and
a sensor arranged at the housing and electrically connected to the processor, the sensor identifying a state and position of the fingers of a user, and the housing being provided with the button.

8. The gamepad for the head-mounted device according to claim 6, further comprising:
a detector for detecting a position of the button, and electrically connected to the processor; and
a force feedback assembly electrically connected to the processor, and the force feedback assembly being fitted with the button to apply a feedback force to the button, the force feedback assembly controlling a magnitude and direction of the feedback force according to the signal transmitted by the processor.

9. The gamepad for the head-mounted device according to claim 8, wherein the button is multiple, and at least one of the buttons is provided with the detector and the force feedback assembly.

10. The gamepad for the head-mounted device according to claim 8, wherein the force feedback assembly comprises:
a motor; and
a push rod assembly fitted with the button and the motor respectively, and the push rod assembly converting rotation of the motor into movement to apply the feedback force to the button.

11. The gamepad for the head-mounted device according to claim 10, wherein the button is a rotatably arranged trigger, and the detector is an angle sensor.

12. The gamepad for the head-mounted device according to claim 8, wherein the force feedback assembly comprises:
an energized coil arranged inside the housing and electrically connected to the processor, the processor controlling a magnitude and direction of current of the energized coil; and
a magnetic member arranged at the button.

13. The gamepad for the head-mounted device according to claim 12, wherein the detector is a Hall sensor, and the Hall sensor is fitted with the magnetic member to sense the position of the button.

14. The gamepad for the head-mounted device according to claim 1, further comprising an external port arranged at the housing, and the external port is adapted to be fitted with an external device to transmit a signal.

15. The gamepad for the head-mounted device according to claim 7, wherein the housing comprises:
a main body portion, the button, the sensor, and the vibration apparatus being arranged at the main body portion respectively; and
a ferrule arranged at the main body portion, the ferrule being a hollow ring and the plurality of positioning light sources being arranged at the ferrule.

16. A head-mounted device, comprising:
a host; and
a gamepad, wherein the gamepad comprises:
a housing;
a processor arranged inside the housing and in signal transmission with a host of the head-mounted device;
a driving apparatus arranged inside the housing and electrically connected to the processor to receive an instruction signal transmitted by the processor; and
a vibration apparatus arranged inside the housing, the vibration apparatus having a plurality of different vibration frequencies, and the driving apparatus being connected to the vibration apparatus to control, according to the received instruction signal, the vibration apparatus to vibrate at the corresponding vibration frequencies,
wherein the processor being in signal transmission with to the host.

17. The head-mounted device according to claim 16, wherein the instruction signal is an audio signal, and the driving apparatus controls, according to the received audio signal, the vibration apparatus to vibrate.

18. The head-mounted device according to claim 16, wherein the processor is provided with a wireless transmission module, and the wireless transmission module is in wireless signal transmission with the host.

19. The head-mounted device according to claim 16, wherein a buffer piece is arranged between the vibration apparatus and an inner circumferential wall of the housing.

20. The head-mounted device according to claim 16, wherein the gamepad further comprises a mounting bracket, the mounting bracket is sleeved on the vibration apparatus, and the mounting bracket is fixed to an inner wall of the housing to locate the vibration apparatus in the housing.
